(19) United States
(12) Patent Application Publication
(10) Pub. No.: US 2018/0034001 A1
(43) Pub. Date: Feb. 1, 2018

(54) WINDOW FOR A DISPLAY DEVICE AND A FLEXIBLE DISPLAY DEVICE INCLUDING THE SAME

(71) Applicant: SAMSUNG DISPLAY CO., LTD., YONGIN-SI (KR)

(72) Inventors: SEONG-JIN HWANG, Suwon-si (KR); Jong-Hwan CHO, Ansan-si (KR); Myung-Hwan KIM, Seongnam-si (KR); Ji-Yeon KIM, Incheon (KR); lk-Hyung PARK, Suwon-si (KR)

(21) Appl. No.: 15/629,186

(22) Filed: Jun. 21, 2017

(30) Foreign Application Priority Data
Jul. 27, 2016 (KR) 10-2016-0095703

(51) Int. Cl. H01L 51/52; H01L 27/32; C03C 17/32; H01L 51/00

(52) U.S. Cl. CPC H01L 51/5253; H01L 51/5237; H01L 51/0097; H01L 27/3258; H01L 27/3262; H01L 27/323; H01L 51/5281; C03C 17/322; C03C 17/324; C03C 17/326; H01L 2251/558; H01L 2251/5338; G06F 3/041

(57) ABSTRACT

A window for a display device including a glass layer and a functional coating layer disposed on the glass layer. The functional coating layer may have an elastic modulus less than an elastic modulus of the glass layer. A thickness of the functional coating layer may be in a range from about 1 micrometer (um) to about 10 um.

### CROSS-REFERENCE TO RELATED APPLICATION

This application claims priority under 35 U.S.C. §119 to Korean Patent Application No. 10-2016-0095703 filed on Jul. 27, 2016 in the Korean Intellectual Property Office, the disclosure of which is incorporated by reference herein in its entirety.

### TECHNICAL FIELD

Exemplary embodiments of the present invention relate to a display device, and more particularly to a window for a flexible display device and a flexible display device including the same.

### DISCUSSION OF RELATED ART

Flexible display devices that are bendable or foldable during use or manufacturing have been increasingly applied and used.

A display device may include a transparent window. The window covers a display surface on which an image is displayed. The window protects the display device from the occurrence of scratches or the like on the display device.

The window may include a glass material. However, in a flexible display device, the window including the glass material may be relatively easily broken when the flexible display device is bent or folded. When the glass material of the window is broken, a user may become injured. The window may include a plastic material having flexible properties. However, the window including the plastic material may have a relatively low surface hardness. Therefore, scratches on a surface of the window of the flexible display device may occur relatively easily.

### SUMMARY

Exemplary embodiments of the present invention provide a window for a display device with an increased strength, and more particularly a flexible display device including the same.

One or more exemplary embodiments of the present invention provide a window for a display device. The window includes a glass layer. The window also includes a functional coating layer. The functional coating layer is disposed on the glass layer. The functional coating layer has an elastic modulus less than an elastic modulus of the glass layer. A thickness of the functional coating layer is in a range from about 1 micrometer (um) to about 10 um.

According to an exemplary embodiment of the present invention, a thickness of the glass layer may be less than or substantially equal to about 100 um.

According to an exemplary embodiment of the present invention, the glass layer may include a chemical enhancing layer.

According to an exemplary embodiment of the present invention, the functional coating layer may include an urethane-based resin, an epoxy-based resin, a polyester-based resin, a polyether-based resin, an acrylate-based resin, an acrylonitrile butadiene styrene (ABS) resin, or a rubber.

According to an exemplary embodiment of the present invention, the functional coating layer may include polyurethane, a combination of polyurethane and a rubber, or a combination of polyurethane and an acrylic monomer.

According to an exemplary embodiment of the present invention, the elastic modulus of the functional coating layer may be in a range from about 1.52 GPa to about 5 GPa.

According to an exemplary embodiment of the present invention, the functional coating layer may be combined with the glass layer.

According to an exemplary embodiment of the present invention, the functional coating layer may be disposed on an entire surface of the glass layer.

According to an exemplary embodiment of the present invention, a light transmittance of the functional coating layer may be greater than or substantially equal to about 88%.

According to an exemplary embodiment of the present invention, the window may have an impact resistance as indicated by a drop height of at least about 6 cm as determined by a pen drop measurement using a pen of about 5.7 g.

According to an exemplary embodiment of the present invention, the window may have a radius of curvature less than or substantially equal to about 4.5 mm.

One or more exemplary embodiments of the present invention provide a display device. The display device includes a flexible display panel. The display device also includes a window. The window is disposed on the display panel. The window includes a glass layer. The window also includes a functional coating layer. The functional coating layer is disposed between the glass layer and the display panel. A thickness of the functional coating layer may be in a range from about 1 um to about 10 um.

According to an exemplary embodiment of the present invention, an elastic modulus of the functional coating layer may be less than an elastic modulus of the glass layer.

According to an exemplary embodiment of the present invention, a thickness of the glass layer may be less than or substantially equal to about 100 um.

According to an exemplary embodiment of the present invention, the glass layer may include a chemical enhancing layer.

According to an exemplary embodiment of the present invention, the functional coating layer may be combined with the glass layer.

According to an exemplary embodiment of the present invention, the functional coating layer may be disposed on an entire surface of the glass layer.

According to an exemplary embodiment of the present invention, the flexible display device may be bent or folded in order that portions of a surface of the display panel face each other.

According to an exemplary embodiment of the present invention, the display panel may include a flexible substrate; at least one transistor disposed on the substrate; an insulation layer covering the transistor; an organic light-emitting element disposed on the insulation layer and electrically connected to the transistor; and an encapsulation member disposed on the substrate. The organic light-emitting element may emit light from an organic light-emitting layer disposed between opposing electrodes.

According to an exemplary embodiment of the present invention, the display device may further include a touch sensing member. The display device may also include an optical film. The touch sensing member and the optical film may be disposed between the display panel and the window.

### BRIEF DESCRIPTION OF THE DRAWINGS

These and/or other aspects will become more apparent and more readily appreciated from the following description of the exemplary embodiments, taken in conjunction with the accompanying drawings, in which:

FIG. 1 is a perspective view illustrating a flexible display device according to an exemplary embodiment of the present invention;

FIG. 2 is a cross-sectional view illustrating a stacked structure of a flexible display device of FIG. 1 according to an exemplary embodiment of the present invention;

FIG. 3 is a cross-sectional view illustrating a flexible display device of FIG. 2 according to an exemplary embodiment of the present invention;

FIG. 4 is a cross-sectional view illustrating an unfolded state of a window of FIG. 3 according to an exemplary embodiment of the present invention; and

FIG. 5 is a cross-sectional view illustrating a folded state of a window of FIG. 3 according to an exemplary embodiment of the present invention.

### DETAILED DESCRIPTION OF THE EMBODIMENTS

Exemplary embodiments of the present invention will be described below in more detail with reference to the accompanying drawings. In this regard, the exemplary embodiments may have different forms and should not be construed as being limited to the exemplary embodiments of the present invention described herein.

Like reference numerals may refer to like elements throughout the specification and drawings.

Sizes of elements in the drawings may be exaggerated for clarity of description.

It will be understood that when a component, such as a layer, a film, a region, or a plate, is referred to as being “on” another component, the component can be directly on the other component or intervening components may be present.

Hereinafter, a window for a display device and a flexible display device including the same in accordance with exemplary embodiments of the present invention will be described in detail with reference to the accompanying drawings.

FIG. 1 is a perspective view illustrating a flexible display device according to an exemplary embodiment of the present invention.

Referring to FIG. 1, a flexible display device 10 may have flexible properties. The flexible display device 10 may also be bendable or foldable. Since an area of the flexible display device 10 may be reduced due to folding the flexible display device 10, the flexible display device 10 may be stored more easily when folded. A user may use the flexible display device 10 by unfolding the flexible display device 10.

As illustrated in FIG. 1, the flexible display device 10 may include a first surface 10a. An image may be displayed on the first surface 10a. The flexible display device 10 may also include a second surface 10b. The second surface 10b may face the first surface 10a. According to an exemplary embodiment of the present invention, when the flexible display device 10 is bent or folded, portions of the second surface 10b may face each other. As illustrated in FIG. 1, the flexible display device 10 may be bent or folded once. However, exemplary embodiments of the present invention are not limited thereto. For example, the flexible display device 10 may be bent or folded at least two times. A folding direction or a folding form of the flexible display device 10 may be variously modified and is not limited to the illustration in FIG. 1.

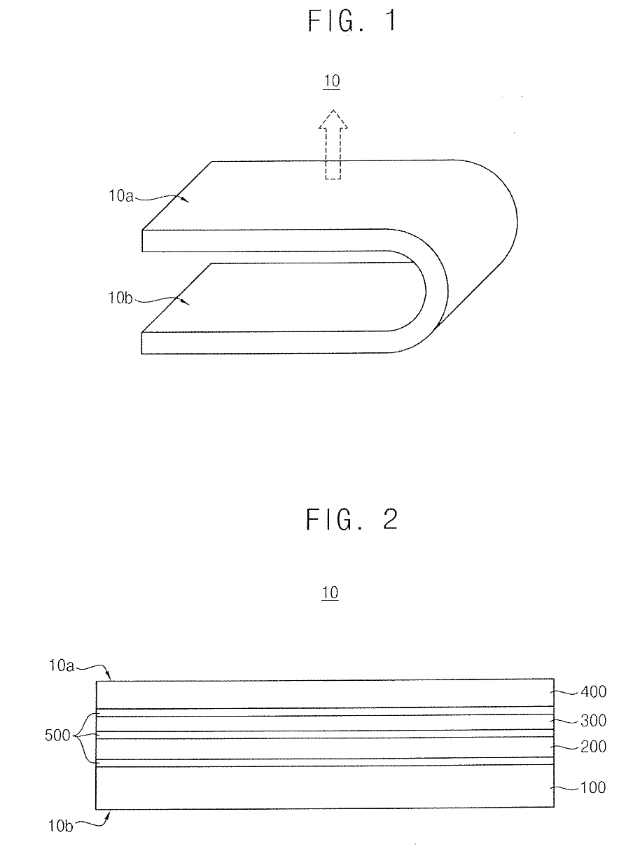

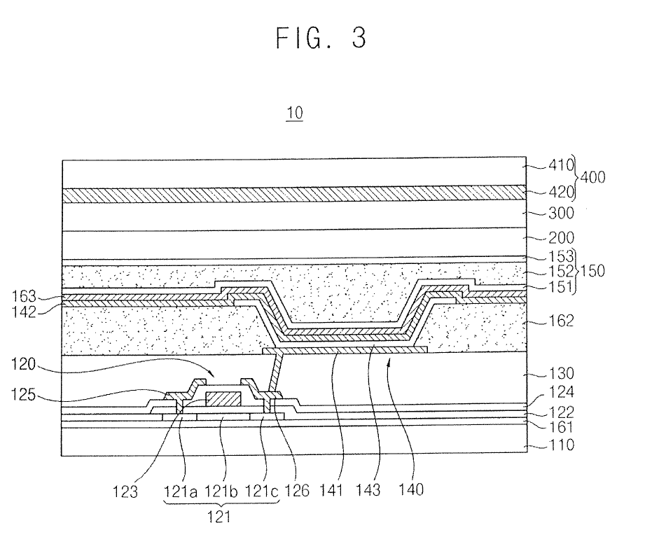

FIG. 2 is a cross-sectional view illustrating a stacked structure of a flexible display device of FIG. 1 according to an exemplary embodiment of the present invention. FIG. 3 is a cross-sectional view illustrating a flexible display device of FIG. 2 according to an exemplary embodiment of the present invention.

Referring to FIGS. 2 and 3, the flexible display device 10 may include a display panel 100, a touch sensing member 200, an optical film 300, and a window 400. The display panel 100, the touch sensing member 200, the optical film 300, and the window 400 may be stacked in a direction from the second surface 10b to the first surface 10a.

The display panel 100 may display an image. The display panel 100 may be flexible. The display panel 100 may include a plurality of pixels. Since each pixel may emit light, the display panel 100 may realize a predetermined image. For example, the display panel 100 may display an image to the first surface 10a of the flexible display device 10.

The display panel 100 may be an organic light-emitting display panel. However, exemplary embodiments of the present invention are not limited thereto. For example, the display panel 100 may be a liquid crystal display panel or a plasma display panel.

Referring to FIG. 3, the display panel 100 may include a flexible substrate 110, at least one transistor 120, an insulation layer 130, an organic light-emitting element 140, and an encapsulation member 150. The transistor 120 may be disposed on the substrate 110. The insulation layer 130 may cover the transistor 120. The organic light-emitting element 140 may be disposed on the insulation layer 130. The encapsulation member 150 may be disposed on the substrate 110. The encapsulation member 150 may encapsulate the organic light-emitting element 140. The organic light-emitting element 140 may be electrically connected to the transistor 120. The organic light-emitting element 140 may emit light from an organic light-emitting layer. The organic light-emitting layer may be disposed between opposing electrodes.

The substrate 110 may include a flexible material. The flexible material may be bendable or foldable. For example, the substrate 110 may include a plastic such as polyimide (PI), polyethylene naphtahlate (PEN), polyethylene terephthalate (PET), polyether ether ketone (PEEK), polyethersulfone (PES), polymethyl methacrylate (PMMA), polycarbonate (PC), and/or polypropylene (PP). Alternatively, the substrate 110 may include a thin plate glass or a thin metal film.

A buffer layer 161 may be formed on the substrate 110. The buffer layer 161 may planarize a top surface of the substrate 110. The buffer layer 161 may decrease or prevent the penetration of impurities into the substrate 110. The buffer layer 161 may have a single layer structure. Alternatively, the buffer layer 161 may have a multi-layered structure. The buffer layer 161 may include a layer including an inorganic material such as silicon oxide and/or silicon nitride. The buffer layer 161 may be formed by various deposition methods.

A pixel circuit unit may be disposed on the buffer layer 161. The pixel circuit unit may include at least one transistor 120. The pixel circuit unit may also include at least one capacitor. FIG. 3 illustrates a top-gate type transistor. The top-gate type transistor may include an active pattern 121, a gate electrode 123, a source electrode 125, and a drain electrode 126. The active pattern 121, the gate electrode 123, the source electrode 125, and the drain electrode 126 may be arranged over the substrate 110. However, exemplary embodiments of the present invention are not limited thereto. For example, various types of transistors may be used, such as a bottom-gate type transistor.

The active pattern 121 may be formed on the buffer layer 161. The active pattern 121 may include a semiconductor material. For example, the active pattern 121 may include amorphous silicon (a-Si) or poly-crystalline silicon (poly-Si). The active pattern 121 may include a source region 121a, a drain region 121c, and a channel region 102b. The source region 121a and the drain region 121c may be respectively connected to the source electrode 125 and the drain electrode 126. The channel region 121b may be disposed between the source region 121a and the drain region 121c.

A gate insulation layer 122 may be formed on the active pattern 121. The gate insulation layer 122 may have a single layer structure. Alternatively, the gate insulation layer 122 may have a multi-layered structure. The gate insulation layer 122 may include a layer including an inorganic material such as silicon oxide and/or silicon nitride. The gate insulation layer 122 may insulate the gate electrode 123 and the active pattern 121 from each other.

The gate electrode 123 may be formed on the gate insulation layer 122. The gate electrode 123 may substantially overlap the channel region 121b of the active pattern 121. The gate electrode 123 may be connected to a gate line. The gate line may apply ON/OFF signals to the transistor 120. The gate electrode 123 may have a single layer structure. Alternatively, the gate electrode 123 may have a multi-layered structure. The gate electrode 123 may include a layer including a conductive material such as molybdenum (Mo), aluminum (Al), copper (Cu), titanium (Ti), or any combination thereof.

An insulation interlayer 124 may be formed on the gate electrode 123. The insulation interlayer 124 may have a single layer structure. Alternatively, the insulation interlayer 124 may have a multi-layered structure. The insulation interlayer 124 may include a layer including an inorganic material such as silicon oxide and/or silicon nitride. The insulation interlayer 124 may insulate the gate electrode 123 from the source electrode 125 and the drain electrode 126.

The source electrode 125 and the drain electrode 126 may be formed on the insulation interlayer 124. The source electrode 125 may be connected to the source region 121a of the active pattern. The drain electrode 126 may be connected to the drain region 121c of the active pattern 121. The source electrode 125 and the drain electrode 126 may be respectively connected to the source region 121a and the drain region 121c of the active layer 121 through a contact hole. The contact hole may be formed in the gate insulation layer 122 and the insulation interlayer 124. The source electrode 125 and the drain electrode 126 may have a single layer structure. Alternatively, the source electrode 125 and the drain electrode 126 may have a multi-layered structure. The source electrode 125 and the drain electrode 126 may each include a layer including a conductive material selected from molybdenum (Mo), aluminum (Al), copper (Cu), titanium (Ti), or any combination thereof.

The insulation layer 130 may cover the transistor 120. The insulation layer 130 may reduce or prevent a step height caused by the transistor 120. The insulation layer 130 may planarize an upper surface of the substrate 110. Thus, the insulation layer 130 may reduce or prevent the occurrence of defects in the organic light-emitting element 140 due to an unevenness below the insulation layer 130. The insulation layer 130 may have a single layer structure. Alternatively, the insulation layer 130 may have a multi-layered structure. The insulation layer 130 may include a layer including an inorganic material, an organic material, or any combinations thereof.

The transistor 120 may be electrically connected to the organic light-emitting element 140. The organic light-emitting element 140 may emit light. The organic-light emitting element 140 might not emit light. The organic light-emitting element 140 may emit light according to a turn-on state or a turn-off state of the transistor 120.

The organic light-emitting element 140 may be formed on the insulation layer 130. The organic light-emitting element 140 may include a pixel electrode 141, an opposing electrode 142, and an intermediate layer 143. The opposing electrode 142 may be disposed opposite to the pixel electrode 141. The intermediate layer 143 may be disposed between the pixel electrode 141 and the opposing electrode 142. According to an emission direction of the organic light-emitting element 140, a display device may be a bottom emission type, a top emission type or a dual emission type. In a bottom emission type display device, the pixel electrode 141 may be a light-transmitting electrode. The opposing electrode 142 may be a reflective electrode. In a top emission type display device, the pixel electrode 141 may be a reflective electrode. The opposing electrode 142 may be a transflective electrode. In a dual emission type display device, the pixel electrode 141 and the opposing electrode 142 may each be light-transmitting electrodes. FIG. 3 illustrates the flexible display device 10 as a top emission type display device. However, the exemplary embodiments of the present invention are not limited thereto. For example, the flexible display device 10 may be a bottom emission type display device or a dual emission type display device.

The pixel electrode 141 may be patterned. The pixel electrode 141 may be patterned in the form of a discrete island respectively corresponding to each pixel. The pixel electrode 141 may be connected to the transistor 120. The pixel electrode 141 may be connected to the transistor 120 through a via hole. The via hole may be formed in the insulation layer 130.

The pixel electrode 141 may include a transparent electrode layer. The pixel electrode 141 may also include a reflective electrode layer. The reflective electrode layer may reflect light in a direction from the pixel electrode 141 to the opposing electrode 142. When the pixel electrode 141 is an anode, the transparent electrode layer may include a transparent conductive oxide with a relatively high work function, such as indium tin oxide (ITO), indium zinc oxide (IZO), zinc oxide (ZnO), indium oxide (In₂O₃), indium gallium oxide (IGO), aluminum zinc oxide (AZO), or any combination thereof. The reflective electrode layer may include a relatively high reflective metal, such as silver (Ag).

A pixel defining layer 162 may be formed on the insulation layer 130. The pixel defining layer 162 may be formed by a method, such as a spin coating. The pixel defining layer 162 may be formed by using an organic insulating material such as polyimide, polyamide, an acryl resin, benzocyclobutane or a phenol resin. The pixel defining layer 162 may cover an edge portion of the pixel electrode 141. The pixel defining layer 162 may include an opening. The opening may expose at least a center portion of the pixel electrode 141. The opening may correspond to a light-emitting region of the pixel. The intermediate layer 143 may be formed in the opening.

The intermediate layer 143 may include the organic light-emitting layer. The organic light-emitting layer may be configured to emit red, green or blue light. The organic light-emitting layer may include a low molecular weight organic material or a polymer organic material. When the organic light-emitting layer includes the low molecular weight organic material, a hole transport layer (HTL) and a hole injection layer (HIL) may be stacked in a direction from the organic light-emitting layer to the pixel electrode 141. Additionally, an electron transport layer (ETL) and an electron injection layer (EIL) may be stacked in a direction from the organic light-emitting layer to the opposing electrode 142.

The opposing electrode 142 may cover an entire surface of the pixel defining layer 162. The opposing electrode 142 may include a metal. When the opposing electrode 142 is a cathode, the opposing electrode 142 may include a material with a relatively low work function, such as lithium (Li), calcium (Ca), LiF/Ca, LiF/Al, aluminum (Al), magnesium (Mg), or silver (Ag). The metal included in the opposing electrode 142 may be formed as a thin film. The thin film may transmit light therethrough.

A capping layer 163 may be formed on the opposing electrode 142. The capping layer 163 may maintain a work function of the opposing electrode 142. The capping layer 162 may reduce or prevent damage of the organic material included in the intermediate layer 143 when the encapsulation member 150 is formed. The encapsulation member 150 may be formed by a sputtering process or a plasma enhanced chemical vapor deposition (PECVD) process.

The encapsulation member 150 may be formed over an entire surface of the substrate 110. The encapsulation member 150 may protect the organic light-emitting element 140 from external moisture or oxygen. The encapsulation member 150 may include one or more inorganic layers 151 and 153. The encapsulation member 150 may also include one or more organic layers 152. For example, as illustrated in FIG. 3, the encapsulation member 150 may include a first inorganic layer 151, a second inorganic layer 153, and an organic layer 152. The organic layer 152 and the second inorganic layer 153 may be stacked on the first inorganic layer 151. The organic layer 152 and the second inorganic layer 153 stacked on the first inorganic layer 151 may form the encapsulation member 150. The first inorganic layer 151 and the second inorganic layer 153 may each include silicon oxide, silicon nitride, silicon oxynitride, aluminum oxide, titanium oxide, tantalum oxide, hafnium oxide, zinc oxide, or any combination thereof. The organic layer 152 may include polyethylene terephthalate, polyimide, polycarbonate, epoxy, polyethylene, polyacrylate, or any combination thereof.

According to an exemplary embodiment of the present invention, since display panel 100 may include the flexible substrate 110 and the encapsulation member 150 having flexibility, the display panel 100 may be bent, folded, or unfolded.

As illustrated in FIGS. 2 and 3, a touch sensing member 200 may be disposed on the display panel 100. The touch sensing member 200 may include an electrostatic capacitive type sensing member, a resistive type sensing member, an electro-magnetic type sensing member, or an infrared type sensing member. The touch sensing member 200 may be electrically connected to the display panel 100.

As illustrated in FIG. 2, an adhesive member 500 may be disposed between the display panel 100 and the touch sensing member 200. The adhesive member 500 may attach the display panel 100 and the touch sensing member 200 to each other. For example, the adhesive member 500 may include an optically clear adhesive (OCA) or pressure sensitive adhesive (PSA); however, exemplary embodiments of the present invention are not limited thereto.

The optical film 300 may be disposed on the touch sensing member 200. The optical film 300 may include a circular polarization film or a linear polarization film; however, exemplary embodiments of the present invention are not limited thereto. The optical film 300 may reduce or prevent a reflection of external light. Therefore, the optical film 300 may increase a user's ability to observe an image.

FIGS. 2 and 3 illustrate the touch sensing member 200 and the optical film 300 disposed over the display panel 100. However, exemplary embodiments of the present invention are not limited thereto. For example, the touch sensing member 200 and the optical film 300 may be embedded in the display panel 100. Thus, the touch sensing member 200 and the optical film 300 may be disposed between the substrate 110 and the encapsulation member 150 of the display panel 100.

The window 400 may be disposed on the optical film 300. The window 400 may protect the display panel 100, the touch sensing member 200, and the optical film 300. A user may observe an image displayed by the display panel 100 through the window 400.

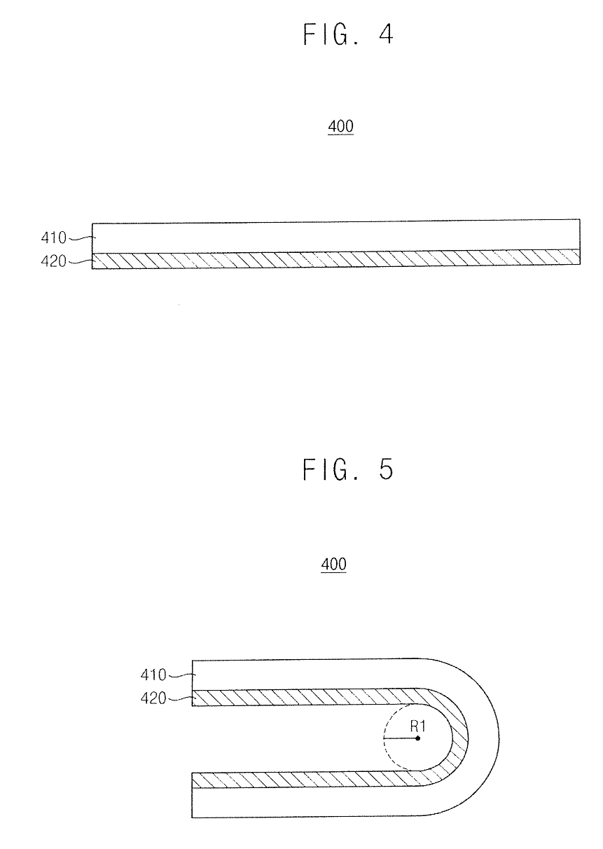

FIG. 4 is a cross-sectional view illustrating an unfolded state of a window of FIG. 3 according to an exemplary embodiment of the present invention. FIG. 5 is a cross-sectional view illustrating a folded state of a window of FIG. 3 according to an exemplary embodiment of the present invention.

Referring to FIGS. 4 and 5, the window 400 may include a glass layer 410. The glass layer 410 may be bendable or foldable. The window 400 may also include a functional coating layer 420. The functional coating layer 420 may be disposed on the glass layer 410.

The glass layer 410 may include a glass material. The glass material may have a relatively high strength, surface flatness, and transparency.

According to an exemplary embodiment of the present invention, the glass layer 410 may include a chemical enhancing layer. The chemical enhancing layer may be formed on an outer surface of the glass layer 410 by, for example, performing a chemically enhancing process. For example, a compressive stress may be formed in the chemical enhancing layer. Additionally, a tensile stress may be formed in a portion of the glass layer 410 disposed inside the chemical enhancing layer. The strength of the glass layer 410 may be increased by forming the chemical enhancing layer in the glass layer 410.

Various methods may be used to form the glass layer 410. According to an exemplary embodiment of the present invention, after preparing a mother glass substrate having a thickness of about 100 micrometer (um) or less, the mother glass substrate may be formed into a glass layer having a predetermined shape through cutting, polishing, and firing. The glass layer may then be chemically enhanced. According to an exemplary embodiment of the present invention, after preparing a relatively thick mother glass substrate, a slimming process may be performed to provide a slimmed mother glass substrate. A shape manufacturing and chemically enhancing process may be performed on the slimmed mother glass substrate. The slimming process may be performed using mechanical methods and/or chemical methods.

The chemically enhancing process may be performed on the shape manufactured glass substrate by firing the glass substrate for about 15 hours to about 18 hours in a temperature from about 400° C. to about 450° C. after exposing an outer surface of the glass substrate to a KNO₃ solution. Sodium (Na) on a surface of the glass substrate may be replaced by potassium (K). Thus, the strength of the surface of the glass substrate may be increased. Since sodium (Na) on the surface of the glass substrate is replaced by potassium (K), the chemical enhancing layer may be formed on the surface of the glass layer 410.

As illustrated in FIG. 5, the window 400 may be bent or folded according to a bending or folding direction of the display panel 100 illustrated in FIG. 1. Layers included in the window 400 may have a relatively small bending stiffness. Therefore, the window 400 may be easily bent or folded. The bending stiffness of a single layer may be calculated by Equation 1:

BS∝E×TH³[Equation 1]

In Equation 1, BS may indicate a bending stiffness of the single layer; E may indicate an elastic modulus of the single layer; and TH may indicate a thickness of the single layer.

The bending stiffness of the glass layer 410 may be proportional to the cube of the thickness of the glass layer 410. Therefore, the thickness of the glass layer 410 may be relatively small so that the glass layer 410 may have a relatively small bending stiffness.

According to an exemplary embodiment of the present invention, the thickness of the glass layer 410 may be less than about 100 um. Therefore, the window 400 including the glass layer 410 may be bent or folded with a relatively small radius of curvature.

When the window 400 is deformed or impacted, the window 400 may be damaged. When the window 400 including the glass layer 410 is deformed or impacted, a tensile stress may be applied on the glass layer 410. The tensile stress may break the glass layer 410. Fine glass fragments formed by a broken glass layer 410 may be scattered. When the glass layer 410 includes the chemical enhancing layer, the tensile stress on the glass layer 410 may be determined by Equation 2:

$$CT = \frac{CS \times DOL}{T - 2 DOL} \qquad [ Equation 2 ]$$

In Equation 2, CT may indicate a tensile stress on the glass layer 410; CS may indicate a compressive stress applied on the surface of the glass layer 410; DOL may indicate a thickness of the chemical enhancing layer; and T may indicate a thickness of the glass layer 410.

As shown in Equation 2, the tensile stress CT on the glass layer 410 may increase as the thickness of the glass layer 410 decreases. Additionally, the glass layer 410 may have a relatively large tensile stress CT. The tensile stress CT of the glass layer 410 may be about three times greater than that of a general glass layer when substantially the same compressive stress are applied to a surface of the glass layer 410. When a relatively large tensile stress CT is applied to the glass layer 410, the glass layer 410 may break. Therefore, fine glass fragments formed when the glass layer 410 broke may be scattered. A user may then be exposed to and injured by the scattered glass fragments.

The window 400 may include the glass layer 410. The glass layer 410 may be chemically enhanced. The glass layer 410 may also have a relatively small thickness. Therefore, the bending stiffness of the glass layer 410 may be a relatively small and the window 400 may be bent or folded. However, the glass layer 410 may be broken or scattered by an impact on the window 400. Accordingly, a countermeasure may be needed to reduce or prevent the breaking or scattering of the glass layer 410.

The functional coating layer 420 may be disposed on the glass layer 410. The functional coating layer 420 may increase the strength of the window 400. The functional coating layer 420 may reduce or prevent the scatter of the glass layer 410.

According to an exemplary embodiment of the present invention, the functional coating layer 420 may be disposed on a surface of the glass layer 410 facing the display panel 100. For example, the functional coating layer 420 may be disposed between the glass layer 410 and the display panel 100. Therefore, the glass layer 410 may be disposed on the first surface 10a of the flexible display device 10.

When a portion of the glass layer 410 is impacted, the functional coating layer 420 may offset a tensile stress formed on the glass layer 410 by the impact. Accordingly, the functional coating layer 420 may reduce or prevent the glass layer 410 from breaking. The functional coating layer 420 may also absorb an impact energy formed when the glass layer 410 is broken. Therefore, the functional coating layer 420 may reduce or prevent fine glass fragments from being scattered. The functional coating layer 420 may include an elastic material. The elastic material may absorb the impact energy. The functional coating layer 420 may include a flexible material. The flexible material may be bendable or foldable. Since the functional coating layer 420 may be in direct contact with the glass layer 410, an increased adhesion between the functional coating layer 420 and the glass layer 410 may be needed.

According to an exemplary embodiment of the present invention, the functional coating layer 420 may include a urethane-based resin, an epoxy-based resin, a polyester-based resin, a polyether-based resin, an acrylate-based resin, an ABS resin, and/or rubber. For example, the functional coating layer 420 may include polyurethane (PU), a combination of polyurethane and rubber, or a combination of polyurethane and acrylic monomer.

According to an exemplary embodiment of the present invention, the functional coating layer 420 may be combined with the glass layer 410. The functional coating layer 420 may be formed on the glass layer 410 by using, for example, a coating method. For example, the functional coating layer 420 may be formed on the glass layer 410 by using a slip coating method, a bar coating method, or a spin coating method. According to an exemplary embodiment of the present invention, the functional coating layer 420 may be formed on an entire surface of the glass layer 410.

A thickness of the functional coating layer 420 may be in a range from about 1 um and about 10 um, for example, from about 3 um to about 10 um. When the thickness of the functional coating layer 420 is less than about 1 um, the functional coating layer 420 might not absorb the impact energy when the glass layer 410 is impacted. When the thickness of the functional coating layer 420 is greater than about 10 um, the bending stiffness of the functional coating layer 420 may increase as described in Equation 1. Therefore a deformation of the glass layer 410 by the impact may increase and the tensile stress on the glass layer 410 may increase.

The functional coating layer 420 may have an elastic modulus. The elastic modulus may be less than the elastic modulus of the glass layer 410. The functional coating layer 420 may include an elastic material. The elastic material may absorb the impact energy occurring from the glass layer 410 being impacted. Since the bending stiffness of the functional coating layer 420 may be proportional to the elastic modulus of the functional coating layer 420 as described in Equation 1, the functional coating layer 420 may have an elastic modulus less than that of the glass layer 410. Therefore, the functional coating layer 420 might not alter the flexible properties of the window 400.

According to an exemplary embodiment of the present invention, the elastic modulus of the functional coating layer 420 may be in a range from about 1.52 gigapascal (GPa) to about 5 GPa, for example, from about 2 GPa to about 4 GPa. For example, the elastic modulus of the glass layer 410 directly combined with the functional coating layer 420, may be about 69.3 GPa. When the elastic modulus of the functional coating layer 420 is less than about 1.52 GPa, the degree of the deformation of the glass layer 410 by impact may increase. Therefore, a tensile stress on the glass layer 410 may increase. When the elastic modulus of the functional coating layer 420 is greater than about 5 GPa, the functional coating layer 420 might not absorb the impact energy occurred when the fine glass fragments are scattered.

According to an exemplary embodiment of the present invention, a light transmittance of the functional coating layer 420 may be greater than or equal to about 88%. The light transmittance of the functional coating layer 420 may be greater than or equal to about 90%. Light emitted from the pixels of the display panel 100 may be visible to a user through the window 400. The light emitted from the pixels may transmit the functional coating layer 420 disposed on the entire surface of the glass layer 410. The functional coating layer 420 may have enough light transmittance to reduce or prevent a luminance of light emitted from the display panel 100.

When the window 400 is impacted, the functional coating layer 420 may reduce or prevent breakage of the glass layer 410. Therefore, an impact resistance of the window 400 may be increased. For example, the window 400 may have an impact resistance as indicated by a drop height of at least 6 centimeter (cm) as determined by a pen drop measurement using a 5.7 gram pen. The window 400 may be not broken when the 5.7 gram pen is dropped at a height less than or equal to about 6 cm from the window 400.

As illustrated in FIG. 5, the window 400 may be folded so that portions of the functional coating layer 420 may face each other. According to an exemplary embodiment of the present invention, the window 400 may have a radius curvature RI less than or equal to about 4.5 millimeter (mm). The functional coating layer 420 might not detach from the glass layer 410 in the radius curvature RI less than or equal to about 4.5 mm. Furthermore, the functional coating layer 420 may maintain adhesion with the glass layer 410.

Exemplary embodiments of the present invention will be explained in detail below with reference to experimental results. Exemplary embodiments of the present invention described below are for description purposes and exemplary embodiments of the present invention are not limited thereto.

Tables 1 to 3 illustrate experimental results observing scatter preventing effect, impact resistance, and curvature reliability of windows according to exemplary embodiments of the present invention and comparative examples. The scatter preventing effect represents whether fine glass fragments are scattered or not when a window is broken. The impact resistance represents the drop height in order to break a window when a 5.7 gram pen is dropped. The curvature reliability represents whether a window is detached or not when the window is bended in about 4.5 mm radius curvature.

Table 1 illustrates experimental results observing scatter preventing effect, impact resistance, and curvature reliability of the window with changing the material composition and the thickness of the functional coating layer. A polyethylene terephthalate (PET) layer having about 50 um thickness and a pressure sensitive adhesive (PSA) layer having about 50 um thickness are stacked on a metal plate, and the functional coating layer and the glass layer are stacked thereon for the experiments.

TABLE 1

| | Material | | Scatter | Impact | | |
|---|---|---|---|---|---|---|
| | (elastic | Thickness | preventing | resistance | Curvature | Window |
| | modulus) | (um) | effect | (cm) | reliability | availability |
| First | Polyurethane | 3 | ◯ | 10 | ◯ | ◯ |
| embodiment | (3.61 GPa) | | | | | |
| Second | | 5 | | 7 | | |
| embodiment | | | | | | |
| Third | | 10 | | 7 | | |
| embodiment | | | | | | |
| First | | 20 | | 6 | X | X |
| comparative | | | | | | |
| example | | | | | | |
| Second | | 25 | | 5 | | |
| comparative | | | | | | |
| example | | | | | | |
| Fourth | Polyurethane + | 3 | | 11 | ◯ | ◯ |
| embodiment | Rubber | | | | | |
| Fifth | (2.78 GPa) | 5 | | 9 | | |
| embodiment | | | | | | |
| Sixth | | 10 | | 8 | | |
| embodiment | | | | | | |
| Third | | 20 | | 5 | | X |
| comparative | | | | | | |
| example | | | | | | |
| Fourth | | 25 | | 4 | | |
| comparative | | | | | | |
| example | | | | | | |
| Seventh | Polyurethane + | 1 | | 6 | | ◯ |
| embodiment | Acrylic | | | | | |
| Eighth | monomer | 3 | | 10 | | |
| embodiment | (4.25 GPa) | | | | | |
| Ninth | | 10 | | 11 | | |
| embodiment | | | | | | |
| Fifth | | 20 | | 7 | X | X |
| comparative | | | | | | |
| example | | | | | | |
| Sixth | | 25 | | 5 | | |
| comparative | | | | | | |
| example | | | | | | |

Referring to Table 1, the windows have a scatter preventing effect in the exemplary embodiments of the present invention and comparative examples. The windows according to exemplary embodiments of the present invention have impact resistances greater than or equal to about 6 cm and curvature reliability. However, the windows according to comparative examples have impact resistances less than or equal to about 5 cm or do not have curvature reliability. Therefore, the windows according to exemplary embodiments of the present invention may be suitable to be included as windows in a flexible display device. However, the windows according to comparative examples are not suitable to be included as windows in a flexible display device.

Table 2 illustrates experimental results observing scatter preventing effect, impact resistance, and curvature reliability of the window without the functional coating layer. A polyethylene terephthalate (PET) layer having about 50 um thickness and a pressure sensitive adhesive (PSA) layer having about 50 um thickness are stacked on a metal plate, and the glass layer 410 are stacked thereon for the experiments.

TABLE 2

| | Material | | Scatter | Impact | | |
|---|---|---|---|---|---|---|
| | (elastic | Thickness | preventing | resistance | Curvature | Window |
| | modulus) | (um) | effect | (cm) | reliability | availability |
| Seventh | X | X | X | 5 | ◯ | X |
| comparative | | | | | | |
| example | | | | | | |

Referring to Table 2, the window according to seventh comparative example has curvature reliability, however, does not have scatter preventing effect and has impact resistance less than or equal to about 5 cm. Therefore, the window according to seventh comparative example is not suitable to be included as a window in a flexible display device.

Table 3 illustrates experimental results observing scatter preventing effect, impact resistance and curvature reliability of the window with a generally used optically cleared adhesive (OCA) film instead of the functional coating layer. A polyethylene terephthalate (PET) layer having about 50 um thickness and a pressure sensitive adhesive (PSA) layer having about 50 um thickness are stacked on a metal plate. The optically cleared adhesive (OCA) including a pressure sensitive adhesive (PSA) layer having about 30 um thickness and a polyethylene terephthalate (PET) layer having about 50 um thickness, and the glass layer 410 are stacked thereon for the experiments.

TABLE 3

| | Material | | Scatter | Impact | | |
|---|---|---|---|---|---|---|
| | (elastic | Thickness | preventing | resistance | Curvature | Window |
| | modulus) | (um) | effect | (cm) | reliability | availability |
| Eighth | PSA/PET | 30/50 | X | 3 | X | X |
| comparative | | | | | | |
| example | | | | | | |

Referring to Table 3, the window according to the eighth comparative example has scatter preventing effect. However, the window according to the eighth comparative example has an impact resistance equal to about 3 cm and does not have curvature reliability. Therefore, the window according to eighth comparative example is not suitable to be included as a window for a flexible display device.

The windows for a display device and a flexible display device according to exemplary embodiment of the present invention may be included in various display devices. For example, the windows and the flexible display devices may be applied to personal computers, notebook computers, mobile phones, smart phones, tablet computers, personal media players (PMP), personal digital assistance (PDA), or MP3 players; however, exemplary embodiments of the present invention are not limited thereto.

Although windows for a display device and a flexible display device including the same in accordance with exemplary embodiments of the present invention have been described with reference to the accompanying drawings, exemplary embodiments of the present invention are not limited thereto. Those skilled in the art will readily appreciate that many modifications are possible in the exemplary embodiments of the present invention without materially departing from the scope of the present inventive concept.

What is claimed is:

1. A window for a display device, comprising:
a glass layer; and
a functional coating layer disposed on the glass layer, the functional coating layer having an elastic modulus less than an elastic modulus of the glass layer,
wherein a thickness of the functional coating layer is in a range from about 1 micrometer (um) to about 10 um.

2. The window of claim 1, wherein a thickness of the glass layer is less than or substantially equal to about 100 um.

3. The window of claim 1, wherein the glass layer includes a chemical enhancing layer.

4. The window of claim 1, wherein the functional coating layer includes an urethane-based resin, an epoxy-based resin, a polyester-based resin, a polyether-based resin, acrylate-based resin, an acrylonitrile butadiene styrene (ABS) resin, or a rubber.

5. The window of claim 1, wherein the functional coating includes polyurethane, a combination of polyurethane and a rubber, or a combination of polyurethane and an acrylic monomer.

6. The window of claim 1, wherein the elastic modulus of the functional coating layer is in a range from about 1.52 GPa to about 5 GPa.

7. The window of claim 1, wherein the functional coating layer is combined with the glass layer.

8. The window of claim 1, wherein the functional coating layer is disposed on an entire surface of the glass layer.

9. The window of claim 1, wherein a light transmittance of the functional coating layer is greater than or substantially equal to about 88%.

10. The window of claim 1, wherein the window has an impact resistance as indicated by a drop height of at least about 6 cm as determined by a pen drop measurement using a pen of about 5.7 g.

11. The window of claim 1, wherein the window has a radius of curvature less than or substantially equal to about 4.5 mm.

12. A display device, comprising:
a flexible display panel; and
a window disposed on the display panel,
wherein the window comprises:
a glass layer; and
a functional coating layer disposed between the glass layer and the display panel, and
wherein a thickness of the functional coating layer is in a range from about 1 um to about 10 um.

13. The display device of claim 12, wherein an elastic modulus of the functional coating layer is less than an elastic modulus of the glass layer.

14. The display device of claim 12, wherein a thickness of the glass layer is less than or substantially equal to about 100 um.

15. The display device of claim 12, wherein the glass layer includes a chemical enhancing layer.

16. The display device of claim 12, wherein the functional coating layer is combined with the glass layer.

17. The display device of claim 12, wherein the functional coating layer is disposed on an entire surface of the glass layer.

18. The display device of claim 12, wherein the display device is bent or folded in order that portions of a surface of the display panel face each other.

19. The display device of claim 12, wherein the display panel comprises:
a flexible substrate;
at least one transistor disposed on the substrate;
an insulation layer covering the transistor;
an organic light-emitting element disposed on the insulation layer and electrically connected to the transistor, the organic light-emitting element emitting light from an organic light-emitting layer disposed between opposing electrodes; and
an encapsulation member disposed on the substrate.

20. The display device of claim 12, further comprising a touch sensing member and an optical film disposed between the display panel and the window.
